(19) United States
(12) Patent Application Publication
(10) Pub. No.: US 2020/0058796 A1
(43) Pub. Date: Feb. 20, 2020

(54) DISPLAY PANEL AND DISPLAY DEVICE

(71) Applicants: HKC Corporation Limited, Shenzhen (CN); Chongqing HKC Optoelectronics Technology Co., Ltd., Chongqing (CN)

(72) Inventor: CHUNG-KUANG CHIEN, Chongqing (CN)

(21) Appl. No.: 16/461,375

(22) PCT Filed: Apr. 20, 2017
(86) PCT No.: PCT/CN2017/081227

§ 371 Date: May 16, 2019

(30) Foreign Application Priority Data
Dec. 29, 2016 (CN) 201611248010.2

(51) Int. Cl. H01L 29/786; G02F 1/1368; H01L 27/12

(52) U.S. Cl. CPC H01L 29/78618; G02F 2001/136222; H01L 27/1248; G02F 1/1368

(57) ABSTRACT

This application discloses a display panel and a display device. The display panel includes a substrate, an active switch array and a color filter layer, where the color filter layer is formed on the active switch array, the active switch array includes a metal layer, the metal layer is arranged on the substrate, the substrate is provided thereon with at least two protective layers, the protective layers are covered on the metal layer, the metal layer is separated from the color filter layer by the protective layers.

This application claims priority to Chinese Patent Application No. CN201611248010.2, filed with the Chinese Patent Office on Dec. 29, 2016 and entitled “DISPLAY PANEL AND DISPLAY DEVICE”, which is incorporated herein by reference in its entire.

### TECHNICAL FIELD

This application relates to the technical field of display, and more particularly to a display panel and a display device.

### BACKGROUND

The statements in this section merely provide background information related to the present application and may not constitute prior art.

Displays have numerous advantages, such as a thin body, power savings, no radiation, etc. and are widely used. Most displays in the market are backlight displays, each includes a display panel and a backlight module. Working principle of the display panel is that liquid crystals are put in two parallel glass substrates, and a driving voltage is applied to the two glass substrates to control rotation of the liquid crystals, to refract light rays of the backlight module to generate an image.

Thin film transistor-liquid crystal displays (TFT-LCDs) maintain a leading status in the display field because of low power consumption, excellent image quality, high production yield, and other properties. Similarly, the TFT-LCD includes a display panel and a backlight module. The display panel includes a color filter substrate (CF substrate) and a thin film transistor substrate (TFT substrate), and transparent electrodes exist on respective inner sides of the above substrates. A layer of liquid crystals (LCs) is positioned between the two substrates. The display panel controls the direction of the LCs through an electric field to change the polarized state of light, and realizes penetration and obstruction of a light path via a polarizing plate, so as to realize the propose of display.

The color filter on TFT (COT) technology has been widely applied to thin film transistor display products in recent years, and the process thereof is beneficial to the development of application of large-sized and curved surface displays.

In a process of applying the COT technology to a TFT substrate, a metal layer is easily disconnected, and then the substrate is scrapped, thereby increasing scrap costs.

### SUMMARY

This application provides a display panel and a display device which can reduce disconnection of a metal layer and improve the production yield.

The purpose of this application is realized by the following technical solution: A display panel, including: a substrate; an active switch array; and a color filter layer formed on the active switch array, where the active switch array includes a metal layer, and the metal layer is arranged on the substrate, the substrate is provided thereon with a protective layer, and the protective layer includes at least two silicon nitride layers and two silicon oxide layers; the silicon nitride layers and the silicon oxide layers are stacked alternately, the metal layer is covered by the protective layer, and the metal layer is separated from the color filter layer by the protective layer, the metal layer includes a first metal layer which is covered with the protective layer, and the color filter layer is directly covered on the protective layer; the first metal layer includes a source metal layer and a drain metal layer, where the source metal layer is connected to a source driver of the display panel; the drain metal layer is connected to a pixel electrode of the display panel; the source metal layer and/or the drain metal layer is covered by the protective layer; the first metal layer is made of aluminum or aluminum alloy; the metal layer also includes a second metal layer, where the width at bottom of the second metal layer is greater than a width of the top of the second metal layer: the first metal layer is connected to a row scan driver of the display panel; the second metal layer is of a three-layer structure includes a first high-adhesion metal layer, an intermediate conducting layer and a second high-adhesion metal layer which are connected to the substrate in sequence from bottom to top, and both the first high-adhesion metal layer and the second high-adhesion metal layer are made of molybdenum or molybdenum alloy; an insulation layer is arranged between the second metal layer and the first metal layer, and the insulation layer is made of silicon oxide or silicon nitride.

This application also discloses a display panel, including: a substrate; an active switch array; and a color filter layer formed on the active switch array, the active switch array includes a metal layer, where the metal layer is arranged on the substrate, the substrate is provided thereon with at least two protective layers, the protective layers are covered on the metal layer, and the metal layer is separated from the color filter layer by the protective layers.

Optionally, the protective layer includes silicon oxide layers or silicone nitride layers.

Optionally, the protective layer includes silicon nitride layers and silicon oxide layers; the silicon nitride layers and the silicon oxide layers are stacked.

Optionally, the protective layer includes silicon nitride layers and silicon oxide layers; the silicon nitride layers and the silicon oxide layers are stacked.

Optionally, the metal layer includes a first metal layer, where the protective layer is covered on the first metal layer; and the color filter layer is directly covered on the protective layer.

Optionally, the first metal layer includes a source metal layer and a drain metal layer, where the source metal layer is connected to a source driver of the display panel; the drain metal layer is connected to a pixel electrode of the display panel; and the protective layer is covered on the source metal layer and/or the drain metal layer.

Optionally, the first metal layer is made of aluminum or aluminum alloy.

Optionally, the metal layer includes a second metal layer, where the width at bottom of the second metal layer is greater than that at the top, and the first metal layer is connected to a row scan driver of the display panel.

Optionally, the section of the second metal layer is trapezoid.

Optionally, isosceles trapezoid is optional for the section of the second metal layer is isosceles trapezoid.

Optionally, a semiconductor layer is arranged on the insulation layer, the source electrode and the drain electrode are arranged at both ends of the semiconductor layer respectively, a channel is arranged between the source electrode and the drain electrode, the semiconductor layer is arranged at the bottom of the channel, both the bottom and side walls of the channel are provided with a protective layer.

Optionally, the second metal layer is of a three-layer structure includes a first high-adhesion metal layer, an intermediate conducting layer and a second high-adhesion metal layer which are connected to the substrate in sequence from bottom to top, and both the first high-adhesion metal layer and the second high-adhesion metal layer are made of molybdenum or molybdenum alloy.

Optionally, an insulation layer is arranged between the second metal layer and the first metal layer, and the insulation layer is made of silicon oxide or silicon nitride.

Optionally, the thickness of the intermediate conducting layer is greater than that of the first high-adhesion metal layer and the second high-adhesion metal layer.

Optionally, resistance property of the high-adhesion metal layer is inferior to that resistance property of the first high-adhesion metal layer and the second high-adhesion metal layer.

Optionally, the width of the second high-adhesion metal layer is identical to that at the top of the intermediate conducting layer.

Optionally, the width of the first high-adhesion metal layer is identical to that at the bottom of the intermediate conducting layer, and the width of the second high-adhesion metal layer is identical to that at the top of the intermediate conducting layer.

This application also discloses a display device, the display device includes a backlight module and the display panel, the display panel including: a substrate; an active switch array; and a color filter layer formed on the active switch array, the active switch array includes a metal layer, where the metal layer is arranged on the substrate, the substrate is provided thereon with at least two protective layers, the protective layers are covered on the metal layer, and the metal layer is separated from the color filter layer by the protective layers, so that if the color filter layer is required to be reworked, the protective layers can protect the metal layer.

The inventor finds through research that for the display panel made by the COT technique, if it is found that a problem occurs in the manufacture process, the region the problem occurs in the manufacture process is reworked using a cleaning agent to eliminate the problem. However, in the reworking process, cleaning agent may corrode the metal layer of the liquid crystal panel, so that the problem of line disconnection may be generated. The existing method tends to directly scrap glass rather than rework, thereby causing scrap costs to be increased. In this application, by arranging the protective layer which is covered on the metal layer, when the region of the substrate the problem occurs in the manufacture process is reworked using the COT technique, the protective layer can effectively avoid the direct corrosion of the cleaning agent o the metal layer of the liquid crystal panel, so that the metal layer can be kept in good condition, thereby avoiding the problem of generating disconnected lines, and then improving the success rate of reworking TFT substrates by the COT technique and reducing scrap costs; moreover, side edges of the metal layer all have metal burrs in terms of microstructure, by arranging at least two protective layers, the metal burrs on the metal layer can be covered, the metal burrs can be effectively prevented from being exposed outside the protective layer, so that the protective layer can protect the metal layer; meanwhile, by arranging the protective layers, the region the problem occurs in the manufacture process can be reworked and repaired rather than scrapping the TFT substrate, thereby being more environmental-friendly.

### BRIEF DESCRIPTION OF DRAWINGS

The drawings included are used for providing further understanding of embodiments of the present application, constitute part of the description, are used for illustrating implementation manners of the present application, and interpreted principles of the present application together with text description. Apparently, the drawings in the following description are merely some embodiments of the present application, and for those ordinary skilled in the art, other drawings can also be obtained according to the drawings without contributing creative labor. In the drawings:

FIG. 1 is a sectional schematic diagram of a display panel of the existing design of this application.

FIG. 2 is one sectional schematic diagram of a protective layer of a display panel of an embodiment of this application.

FIG. 3 is another sectional schematic diagram of a protective layer of a display panel of an embodiment of this application.

FIG. 4 is another sectional schematic diagram of a protective layer of a display panel of an embodiment of this application.

FIG. 5 is another sectional schematic diagram of a protective layer of a display panel of an embodiment of this application.

FIG. 6 is a sectional schematic diagram of a second metal layer of a display panel of an embodiment of this application.

### DETAILED DESCRIPTION

Specific structure and function details disclosed herein are only representative and are used for the purpose of describing exemplary embodiments of this application. However, this application may be specifically achieved in many alternative forms and shall not be interpreted to be only limited to the embodiments described herein.

It should be understood in the description of this application that terms such as “central” “lateral”, “upper”, “lower”, “left”, “right”, “vertical”, “horizontal”, “top”, “bottom”, “inner”, “outer”, etc. indicate direction or position relationships shown based on the drawings, and are only intended to facilitate the description of this application and simplify the description rather than to indicate or imply that the indicated device or element must have a specific direction or constructed and operated in a specific direction, and therefore, shall not be understood as a limitation to this application. In addition, the terms such as “first” and “second” are only used for the purpose of description, rather than being understood to indicate or imply relative importance or hint the number of indicated technical features. Thus, the feature limited by “first” and “second” can explicitly or impliedly comprise one or more features. In the description of this application, the meaning of “a plurality of” is two or more unless otherwise specified. In addition, the term “comprise” and any variant are intended to cover non-exclusive inclusion.

It should be noted in the description of this application that, unless otherwise expressly specified and defined, terms such as “installation,” “connected,” and “connection” shall be understood in broad sense, and for example, may refer to fixed connection or detachable connection or integral connection; may refer to mechanical connection or electrical connection: and may refer to direct connection or indirect connection through an intermediate medium or inner communication of two elements. For those of ordinary skill in the art, the meanings of the above terms in this application be understood according to concrete conditions.

The terms used herein are intended to merely describe concrete embodiments, not to limit the exemplary embodiments. Unless otherwise noted clearly in the context, singular forms “one” and “single” used herein are also intended to comprise plurals. It should also be understood that the terms “comprise” and/or “include” used herein specify the existence of stated features, integers, steps, operation, units and/or assemblies, not excluding the existence or addition of one or more other features, integers, steps, operation, units, assemblies and/or combinations of these.

This application will be described in detail below in combination with the drawings and optional embodiments.

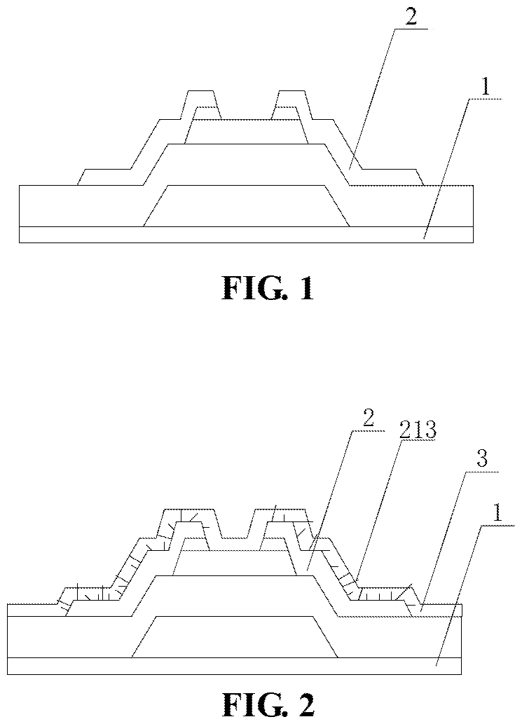

FIG. 1 shows a structure of a thin film transistor. In the process of manufacturing the TFT substrate using the COT technique, if it is found that a problem occurs in the manufacture process of the metal layer 2, the region the problem occurs in the manufacture process is reworked using a cleaning agent to eliminate the problem, a potassium hydroxide solution (KOH solution) is used as the cleaning agent

Therefore, the applicant design an undisclosed display panel, as shown in FIG. 2, after the reworking process, the inventor finds when studying the structure of the thin film transistor that: side edges of the metal layer 2 all have metal burrs 213 in terms of microstructure, by covering a protective layer 3 on the metal layer 2, the metal burrs 213 can be well covered, however, a very small portion of metal burrs 213 penetrate through and extend to the surface of the protective layer 3, causing the metal burrs 213 to be exposed outside the protective layer, when the substrate 1 is reworked, the cleaning agent may corrode the metal burrs 213 exposed outside the protective layer 3, by continuously corroding the metal burrs 213 penetrating through the protective layer 3, corrosion channels are formed in the protective layer 3, the cleaning agent reaches the metal layer 2 along the corrosion channels to corrode the metal layer 2, so that the metal layers 2 are cracked one another.

The inventor finds through research that because of the presence of the metal burrs, not only the protective layer 3 cannot be well adhered to the metal layer 2, but also the problem of line disconnection due to the corrosion of the cleaning agent to the metal layer 2 occurs. Therefore, the inventor proposes a novel technical solution, which can reduce disconnected lines of the metal layer and improve the production yield.

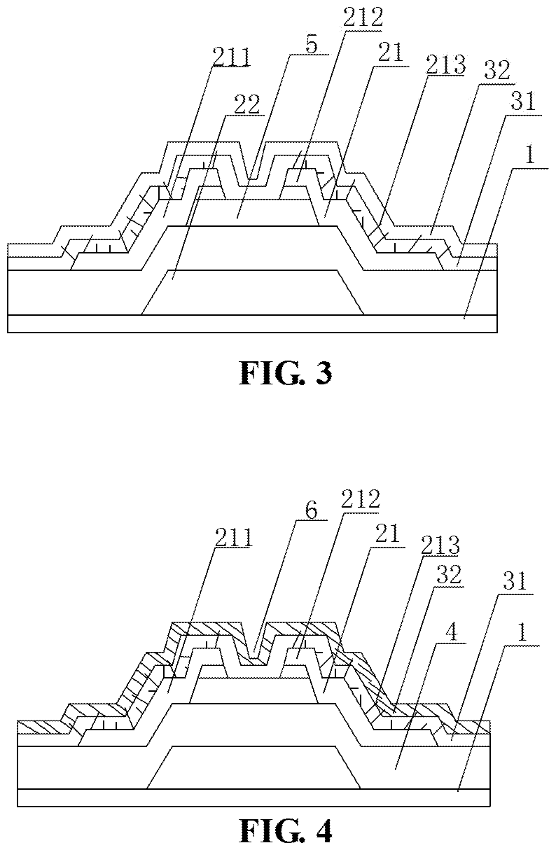

The structural schematic diagram of the display panel of the embodiment of this application is described below with reference to FIG. 3 to FIG. 6.

As shown in FIG. 3, in one or more embodiments, the display panel includes a substrate 1 and a metal layer 2, the metal layer 2 is arranged on the substrate 1, and a protective layer 3 is arranged on the substrate 1. In this application, by arranging the protective layer 3 which is covered on the metal layer 2, when the region of the substrate 1 the problem occurs in the manufacture process is reworked using the COT technique, protective layer 3 can effectively avoid the direct corrosion of the cleaning agent to the metal layer 2 of the liquid crystal panel, so that the metal layer 2 can be kept in good condition, thereby avoiding the problem of generating disconnected lines, and then improving the success rate of reworking the TFT substrates 1 by the COT technique and reducing scrap costs. The protective layer 3 includes two layers, i.e. a first protective layer 31 and a second protective layer 32 respectively, the first protective layer 31 is covered on the substrate 1, and the second protective layer 32 is covered on the first protective layer. Since side edges of the metal layer 2 all have metal burrs 213 in terms of microstructure, by arranging at least two protective layers 3, the metal burrs 213 on be metal layer 2 can be covered. As shown in FIG. 3, the first protective layer 31 can effectively cover the metal burrs 213, the second protective layer 32 can effectively cover the metal burrs 213 exposed outside the first protective layer 31, so that the metal burrs can be effectively prevented from being exposed outside the protective layer 3, and the protective layer 3 can protect the metal layer 2; meanwhile, by arranging the protective layer 3, the region the problem occurs in the manufacture process can be reworked and repaired rather than scrapping the TFT substrate 1, thereby being more environmental-friendly.

The protective layer 3 is a silicon oxide layer, i.e. the protective layer 3 is made of silicon oxide material, and silicon oxide is deposited on the metal layer 2 using the chemical vapor deposition (CVD) technique. After the first chemical vapor deposition on the metal layer 2, the silicon oxide is cooled and solidified to form the first protective layer 31, and then the second chemical vapor deposition is performed on the first protective layer 31 to form the second protective layer 32. The above steps are repeated, so that at least two silicon oxide layers are deposited on the metal layer 2, thereby covering the metal layer 2 and effectively preventing metal burrs 213 from being exposed outside the protective layer 3, so that the protective layer 3 can protect the metal layer 2. Because of relatively stable chemical property, silicon oxide does not react with a potassium hydroxide solution, thereby effectively avoiding the corrosion damage of a cleaning agent to the metal layer 2, so that the metal layer 2 can be well protected; moreover, at least two silicon oxide layers are formed by performing chemical vapor deposition for many times, no raw materials or equipment is required to be additionally replaced halfway, costs of raw materials and storage are reduced, and no new material is required to be added to a material list, thereby facilitating flow management and purchase; meanwhile, since chemical vapor deposition technique is mature, the usage amount of silicon oxide can be well controlled, thereby reducing manufacture costs, and then making the display panel have stronger market competitiveness.

Optionally, the protective layer 3 can be a silicon nitride layer, i.e. the protective layer 3 is made of silicon nitride material, and silicon nitride is deposited on the metal layer 2 using the chemical vapor deposition (CVD) technique. After the first chemical vapor deposition on the metal layer 2, the silicon nitride is cooled and solidified to form the first protective layer 31, and then the second chemical vapor deposition is performed on the first protective layer 31 to form the second protective layer 32. The above steps are repeated, so that at least two silicon nitride layers are deposited on the metal layer 2, thereby covering the metal layer 2 and effectively preventing metal burrs 213 from being exposed outside the protective layer 3, so that the protective layer 3 can protect the metal layer 2. Silicon oxide does not react with the potassium hydroxide solution, thereby effectively avoiding the corrosion damage of a cleaning agent to the metal layer 2, so that the metal layer 2 can be well protected; silicon nitride is an ultrahard material, and the silicon nitride material is resistant to abrasion, is resistant to oxidation at a high temperature and is also resistant to thermal shock: moreover, at least two silicon nitride layers are formed by performing chemical vapor deposition for many times, no raw materials or equipment is required to be additionally replaced halfway, costs of raw materials and storage are reduced, and no new material is required to be added to a material list, thereby facilitating flow management and purchase meanwhile, since chemical vapor deposition technique is mature, the usage amount of silicon nitride can be well controlled, thereby reducing manufacture costs, and then making the display panel have stronger market competitiveness.

As shown in FIG. 4, in one or more embodiments, the outermost layer in the Figure is drawn by shadow, to distinguish the stacked silicon nitride layers from silicon oxide layers adopted by the protective layer 3 only, and not to refer in particular to silicon nitride layers or silicon oxide layers, the protective layer 3 includes silicon nitride layers and silicon oxide layers. The silicon oxide is deposited on the metal layer 2 using the chemical vapor deposition (CVD) technique and is cooled and solidified to form the first protective layer 31, then silicon nitride is deposited on the silicon oxide layer using the chemical vapor deposition technique to form the second protective layer 32. Optionally, the silicon nitride layer is deposited to form the first protective layer 31, then the silicon oxide layer is covered on the silicon nitride layer to form the second protective layer 32. By stacking the silicon nitride layers and silicon oxide layer, the protective layer 3 can be adhered to the metal layer 2, to cover the metal burrs 213 on the metal layer 2, and effectively prevent the metal burrs 213 from being exposed outside the protective layer 3, so that the protective layer 3 can protect the metal layer 2, to effectively avoid the direct corrosion of a cleaning agent to the metal layer 2, so that the metal layer 2 can be kept in good condition, thereby avoiding the problem of line disconnection, and improving the durability of the display panel.

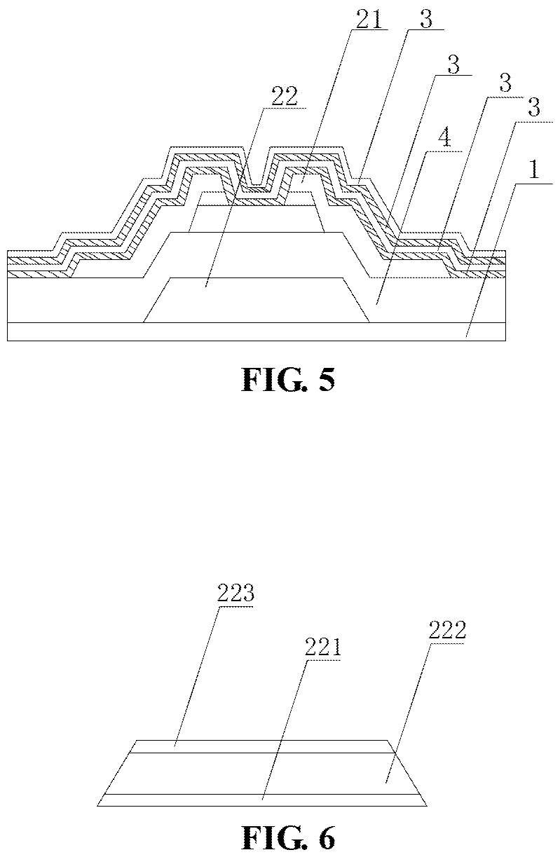

As shown in FIG. 5, the Figure does not show metal burrs 213. See FIG. 3 or FIG. 4 for the schematic diagram of metal burrs 213. In one or more embodiments, the protective layer 3 includes at least two silicon nitride layers and two silicon oxide layers. The silicon oxide is deposited on the metal layer 2 using the chemical vapor deposition technique and is cooled and solidified, then silicon nitride is deposited on the silicon oxide layer using the chemical vapor deposition technique, a second silicon oxide layer is deposited on the silicon nitride layer, and a second silicon nitride layer is deposited on the second silicon oxide layer finally. Of course, the silicon nitride layer can be deposited first, and then the silicon oxide layer is covered on the silicon nitride layer, so that the silicon nitride layers and the silicon oxide layers are alternately stacked. Thus, the protective layer 3 can be adhered to the metal layer 2, to cover the metal burrs 213 on the metal layer 2, and effectively prevent the metal burrs 213 from being exposed outside the protective layer 3, so that the protective layer 3 can protect the metal layer 2.

The metal layer 2 includes a first metal layer 21; a protective layer 3 is covered on the first metal layer; a color filter layer is directly covered on the protective layer 3, the color filter layers are separated from the first metal layer 21 by the protective layer 3, when it is found that a problem occurs at one or more of the color filter layers, the color filter layer is reworked to eliminate the problem using a cleaning agent, so that the protective layer 3 can protect the first metal layer 21, and the protective layer 3 can effectively avoid the direct corrosion of the cleaning agent to the metal layer 2 of the liquid crystal panel, so that the metal layer 2 can be kept in good condition, thereby avoiding the problem of generating disconnected lines. Meanwhile, by arranging the protective layer 3, the color filter layer is reworked and repaired rather than scrapping the TFT substrate 1, thereby being more environmental-friendly.

The first metal layer 21 includes a source metal layer 211 and a drain metal layer 212, the source metal layer 211 is connected to a source driver of the display panel; the drain metal layer 212 is connected to a pixel electrode of the display panel; and the protective layer 3 is covered on the source metal layer 211 and/or the drain metal layer 212.

The first metal layer 21 is made of aluminum or aluminum alloys, because of good electrical conductivity and low resistance property, aluminum or aluminum alloys can meet the requirements of the display panel, moreover, since aluminum or aluminum alloy has the advantages of relatively low price, sufficient supply and convenient purchase, manufacturing costs of the display panel are reduced, so that the display panel has stronger market competitiveness.

The metal layer 2 includes a second metal layer 22, the width at bottom of the second metal layer 22 is greater than that at the top, the first metal layer 21 is connected to a row scan driver of the display panel, since the width at bottom of the second metal layer 22 is greater than that at the top, the manufacture of the second metal layer 22 is more convenient, the shaping is stabler, and the production yield is higher, moreover, the contact area at the bottom of the second metal layer 22 is larger, the paste effect is good, and the fixation is firmer. Trapezoid, especially isosceles trapezoid is optional for the section of the second metal layer 22.

As shown in FIG. 6, in one or more embodiments, the second metal layer 22 of the display panel connected to the row scan driver is of a three-layer structure includes a first high-adhesion metal layer 221, an intermediate conducting layer 222 and a second high-adhesion metal layer 223 which are connected to the substrate 1 in sequence from bottom to top. The intermediate conducting layer 272 may be made of metal with low resistance property, thereby effectively reducing the resistance and parasitic capacitance of the second metal layer 22 of the display panel, and the first high-adhesion metal layer 221 and the second high-adhesion metal layer 223 of the second metal layer 22 are made of metal with good adhesion property. In this way, the intermediate conducting layer 222 may be well adhered and fixed to the first high-adhesion metal layer 221 and the second high-adhesion metal layer 223. Meanwhile, the intermediate conducting layer 222 may be adhered and fixed to the upper layer and the lower layer by the first high-adhesion metal layer 221 and the second high-adhesion metal layer 223 so that the adhesiveness is good, it is difficult the intermediate conducting layer 222 to be separated from the upper layer and the lower layer, not only well satisfying electrical performance of the second metal layer 22 of the display panel, but also being well adhered and fixed to the upper layer and the lower layer, improving production yield and reducing production costs.

The thickness of the intermediate conducting layer 222 is greater than that of the first high-adhesion metal layer 221 and the second high-adhesion metal layer 223. The thickness of the intermediate conducting layer 222 is greater than that of the first high-adhesion metal layer 221 and is also greater than that of the second high-adhesion metal layer 223, the intermediate conducting layer 222 may be made of metal with low resistance property, greater thickness can effectively reduce the resistance and parasitic capacitance of the second metal layer 22 of the panel, the first high-adhesion metal layer 221 and the second high-adhesion metal layer 223 are made of metal with good adhesion property, the intermediate conducting layer 222 is connected to an upper layer and a lower layer by the first high-adhesion metal layer 221 and the second high-adhesion metal layer 223 so that the adhesiveness is good, it is difficult for the intermediate conducting layer 222 to be separated from the upper layer and the lower layer, the first high-adhesion metal layer 221 and the second high-adhesion metal layer 223 are mainly used for adhering to the upper layer and the lower layer, the thickness is small, and costs can be saved. Optionally, the thickness of the intermediate conducting layer 222 may be greater than the sum of the thickness of the first high-adhesion metal layer 221 and the thickness of the second high-adhesion metal layer 223.

Optionally, the width at the bottom of the intermediate conducting layer 222 is greater than that at the top, the width of the first high-adhesion metal layer 221 is identical to that at the bottom of the intermediate conducting layer 222, and the width of the second high-adhesion metal layer 223 is identical to that at the top of the intermediate conducting layer 222. The width at the bottom of the intermediate conducting layer 222 is greater than that at the top, so that manufacture is convenient, shaping is stable and production yield is high, the width of the first high-adhesion metal layer 221 is identical to that at the bottom of the intermediate conducting layer 222, and the width of the second high-adhesion metal layer 223 is identical to that at the top of the intermediate conducting layer 222, so that manufacture is convenient. The area of contact between the intermediate conducting layer 222 and the first high-adhesion metal layer 221 and the second high-adhesion metal layer 223 is maximal, the adhesion effect is preferable, trapezoid, especially isosceles trapezoid is optional for the section of the intermediate conducting layer 222.

The intermediate conducting layer 222 is made of copper, aluminum, silver, gold, chromium, molybdenum or alloy of the above-mentioned metal. Copper, aluminum, silver, gold, chromium, molybdenum or alloy of the above-mentioned metal has good electrical conductivity and low resistance property, which can meet the requirements of the display panel, the intermediate conducting layer 222 is made of copper or copper alloy, which has the higher performance price ratio.

Both the first high-adhesion metal layer 221 and the second high-adhesion metal layer 223 are made of molybdenum or molybdenum alloy. Molybdenum or molybdenum alloy can realize good adhesiveness, can be well adhered to the metal such as copper, aluminum, silver, gold, chromium, molybdenum and the like of the intermediate conducting layer 222 on the one hand, and can be well adhered to other layers such as the substrate 1, the photoresist layer, the insulation layer 4 and the like of the display panel on the other hand. The material is convenient to select, and the manufacture technology is mature. No additional raw materials are required, costs of raw materials and storage are reduced, and no new material is required to be added to a material list, thereby facilitating flow management and purchase; no additional equipment is required to arrange the second high-adhesion metal layer 223 which can share the same equipment with the first high-adhesion metal layer 221, and no additional equipment or materials are required for the final etching.

An insulation layer 4 is arranged between the second metal layer 22 and the first metal layer 21, the insulation layer 4 is made of silicon oxide or silicon nitride, the insulation layer 4 may be arranged using the chemical vapor deposition technique. The chemical vapor deposition technique is mature, the usage amount of silicon nitride can be well controlled, thereby reducing manufacture costs. The insulation layer is of the same material and method as in the subsequent step for arranging the protective layer 3, when the protective layer 3 is arranged in the subsequent step, no raw materials or equipment is required to be additionally replaced, costs of raw materials and storage are reduced, and no new material is required to be added to a material list, thereby facilitating flow management and purchase.

A semiconductor layer 5 is arranged on the insulation layer 4, the source electrode and the drain electrode are arranged at both ends of the semiconductor layer 5 respectively, a channel 6 is arranged between the source electrode and the drain electrode, the semiconductor layer 5 is arranged at the bottom of the channel, both the bottom and side walls of the channel 6 are provided with a protective layer 3, thereby reducing manufacture costs. Moreover, when the protective layer 3 is arranged, no raw materials or equipment is required to be additionally replaced.

As another embodiment of this application, the present embodiment discloses the backlight module and the display panel of the display device. See FIG. 1 to FIG. 6 for specific structures and connection relationships of the display panel, which will not be described in detail herein.

The above contents are further detailed descriptions of this application in combination with specific optional embodiments. However, the specific implementation of this application shall not be considered to be only limited to these descriptions. For those of ordinary skill in the art to which this application belongs, several simple deductions or replacements may be made without departing from the conception of this application, all of which shall be considered to belong to the protection scope of this application.

1. A display panel, comprising:
a substrate;
an active switch array;
a color photoresist layer formed on the active switch array,
wherein the active switch array comprises a metal layer, and the metal layer is arranged on the substrate, the substrate is provided thereon with a protective layer, and the protective layer comprises at least two silicon nitride layers and two silicon oxide layers; the silicon nitride layers and the silicon oxide layers are stacked alternately, the metal layer is covered by the protective layer, and the metal layer is separated from the color filter layer by the protective layer, the metal layer comprises a first metal layer which is covered with the protective layer, and the color filter layer is directly covered on the protective layer; the first metal layer comprises a source metal layer and a drain metal layer, wherein the source metal layer is connected to a source driver of the display panel; the drain metal layer is connected to a pixel electrode of the display panel;
the source metal layer and/or the drain metal layer is covered by the protective layer; the first metal layer is made of aluminium or aluminium alloy; the metal layer also comprises a second metal layer, where the width at bottom of the second metal layer is greater than a width of the top of the second metal layer;
the first metal layer is connected to a row scan driver of the display panel; the second metal layer is of a three-layer structure comprises a first high-adhesion metal layer, an intermediate conducting layer and a second high-adhesion metal layer which are connected to the substrate in sequence from bottom to top, and both the first high-adhesion metal layer and the second high-adhesion metal layer are made of molybdenum or molybdenum alloy;
wherein an insulation layer is arranged between the second metal layer and the first metal layer, and the insulation layer is made of silicon oxide or silicon nitride.

2. A display panel, comprising:
a substrate;
an active switch array: and
a color filter layer formed on the active switch array;
the active switch array comprises a metal layer, wherein the metal layer is arranged on the substrate, the substrate is provided thereon with at least two protective layers, the metal layers is covered by the protective layer, and the metal layer is separated from the color filter layer by the protective layers.

3. The display panel according to claim 2, wherein the protective layer comprises silicon oxide layers or silicon nitride layers.

4. The display panel according to claim 2, wherein the protective layer comprises silicon nitride layers and silicon oxide layers; wherein the silicon nitride layers and the silicon oxide layers are stacked.

5. The display panel according to claim 4, wherein the protective layer comprises at least two silicon nitride layers and two silicon oxide layers; wherein the silicon nitride layers and the silicon oxide layers are alternately stacked.

6. The display panel according to claim 2, wherein the metal layer comprises a first metal layer, wherein the protective layer is covered on the first metal layer; and the color filter layer is directly covered on the protective layer.

7. The display panel according to claim 6, wherein the first metal layer comprises a source metal layer and a drain metal layer, wherein the source metal layer is connected to a source driver of the display panel; the drain metal layer is connected to a pixel electrode of the display panel; and the protective layer is covered on the source metal layer and/or the drain metal layer.

8. The display panel according to claim 6, wherein the first metal layer is made of aluminum or aluminum alloy.

9. The display panel according to claim 6, wherein the metal layer comprises a second metal layer, wherein the width at bottom of the second metal layer is greater than that at the top, and the first metal layer is connected to a row scan driver of the display panel.

10. The display panel according to claim 9, wherein the second metal layer is of a three-layer structure comprises a first high-adhesion metal layer, an intermediate conducting layer and a second high-adhesion metal layer which are connected to the substrate in sequence from bottom to top, and both the first high-adhesion metal layer and the second high-adhesion metal layer are made of molybdenum or molybdenum alloy.

11. The display panel according to claim 9, wherein an insulation layer is arranged between the second metal layer and the first metal layer, and the insulation layer is made of silicon oxide or silicon nitride.

12. A display device, wherein the display device comprises a backlight module and the display panel, wherein the display panel, comprising:
a substrate;
an active switch array: and
a color filter layer formed on the active switch array;
wherein the active switch array comprises a metal layer, wherein the metal layer is arranged on the substrate, the substrate is provided thereon with at least two protective layers, the protective layers are covered on the metal layer, and the metal layer is separated from the color filter layer by the protective layers.

13-20. (canceled)

21. The display panel according to claim 9, wherein the section of the second metal layer is trapezoid.

22. The display panel according to claim 9, wherein isosceles trapezoid is optional for the section of the second metal layer is isosceles trapezoid.

23. The display panel according to claim 9, wherein a semiconductor layer is arranged on the insulation layer, the source electrode and the drain electrode are arranged at both ends of the semiconductor layer 5 respectively, a channel is arranged between the source electrode and the drain electrode, the semiconductor layer is arranged at the bottom of the channel, both the bottom and side walls of the channel are provided with a protective layer.

24. The display panel according to claim 21, wherein the thickness of the intermediate conducting layer is greater than that of the first high-adhesion metal layer and the second high-adhesion metal layer.

25. The display panel according to claim 21, wherein resistance property of the high-adhesion metal layer is inferior to that resistance property of the first high-adhesion metal layer and the second high-adhesion metal layer.

26. The display panel according to claim 21, wherein the width of the second high-adhesion metal layer is identical to that at the top of the intermediate conducting layer.

27. The display panel according to claim 26, wherein the width of the first high-adhesion metal layer is identical to that at the bottom of the intermediate conducting layer, and the width of the second high-adhesion metal layer is identical to that at the top of the intermediate conducting layer.
